(19) United States
(12) Patent Application Publication
(10) Pub. No.: US 2024/0414440 A1
(43) Pub. Date: Dec. 12, 2024

(54) OPTICAL IMAGE STABILISER AND A MOBILE DEVICE EQUIPPED THEREWITH

(71) Applicant: LPKF LASER & ELECTRONICS SE, Garbsen (DE)

(72) Inventors: Roman OSTHOLT, Langenhagen (DE); Norbert AMBROSIUS, Garbsen (DE); Maik BERTKE, Hannover (DE); Svenja SCHUDAK, Hannover (DE)

(21) Appl. No.: 18/699,327

(22) PCT Filed: Aug. 31, 2022
(86) PCT No.: PCT/EP2022/074183

§ 371 Date: Apr. 8, 2024

(30) Foreign Application Priority Data
Oct. 12, 2021 (DE) 10 2021 126 358.1

(51) Int. Cl. H04N 23/68; H04N 23/55

(52) U.S. Cl. CPC H04N 23/685; H04N 23/55

(57) ABSTRACT

An optical image stabilizer for application in a mobile device equipped with a camera lens arrangement includes a carrier, elastic and/or flexible retaining structures that are rib-shaped, and an image sensor arranged on the carrier. The carrier is arranged so as to be movable with regard to a holder of the mobile device by the retaining structures, and is electrically connected by conductor tracks such that, for compensating for movements of the mobile device, the image sensor is arranged on the carrier so as to be movable relative to the holder by actuators. The retaining structures are at least in part elastically deformable and at least portions thereof consist of glass. At least some of the retaining structures have a width in a direction of a movement plane of the image sensor which is smaller than a material thickness in a direction transverse to the movement plane.

### CROSS REFERENCE TO RELATED APPLICATIONS

This application is a U.S. National Phase application under 35 U.S.C. § 371 of International Application No. PCT/EP2022/074183, filed on Aug. 31, 2022, and claims benefit to German Patent Application No. DE 10 2021 126 358.1, filed on Oct. 12, 2021. The International Application was published in German on Apr. 20, 2023 as WO 2023/061657 A1 under PCT Article 21(2).

### FIELD

The invention relates to an optical image stabilizer for application in portable devices, in particular a mobile terminal or an image-recording device, for example a camera, wherein the device is equipped with at least one camera lens arrangement and an image sensor arranged on a carrier, and the carrier is arranged so as to be movable during use vis-à-vis a holder in a housing of the mobile device by means of elastic and/or flexible retaining structures and is electrically connected by way of conductor tracks such that, for the purpose of compensating for bothersome movements of the device, the image sensor is arranged on the carrier so as to be movable relative to the holder by way of actuators. The invention also relates to a portable device equipped with such an optical image stabilizer.

### BACKGROUND

The integration of camera functions in a mobile communications terminal is known. By now, such mobile communications terminals with a camera lens arrangement have become widespread. In this context, the optical image stabilizer serves to correct shaking that occurs when the image is recorded while the device is in motion, for example because the user does not hold said device still.

In the known methods of optical image stabilization (OIS), the movement of the device is detected and the position of an optical lens or a camera lens arrangement is modified by means of actuators in order thus to change the image position of an object on the image sensor and compensate for the movement of the device.

Optical image stabilization is particularly useful in the case of low light or darkness. This is because the camera lens must remain open for longer in such a situation in order to capture sufficient light. In that case, movements of the hand become even more pronounced in photos and videos. Telephoto lenses are also very susceptible. In this case, the effect of movements is amplified by the tighter field of view.

Currently, use is also made of electronic image stabilization (EIS) or digital image stabilization (DIS) methods.

In the case of electronic image stabilization methods, the movement of the hand is detected on the basis of the stored image data and subsequently corrected by image processing programs. Due to the underlying principle, parts of the recording are no longer visible as a result, since the edges serve as a buffer and are sacrificed for the image optimization.

In the case of a mechanism also known as “sensor shift stabilization”, which is known on account of prior public use, the movements of the device are compensated for by actuators and sensors, wherein only the image sensor is moved in different directions. Accordingly, it is thus not the entire camera lens arrangement, for example the lens elements of the camera optics or the entire camera module in its carrier, which is moved; instead, only the actual image sensor is displaced in its position in order to compensate for unwanted device movements or vibrations.

The main advantage here is that the image sensor is much lighter than the lens tube, with the result that the displacement of the image sensor leads to a more reactive and more precise stabilization.

In this respect, a solution has been disclosed, in which the image sensor is arranged on a flexible printed circuit board (FPC) and is thereby provided with limited mobility. The flexible printed circuit board is connected to a rigid circuit board by way of several arms with two anchoring points. The image sensor can be moved in the plane as a result of the flexible arms. Thus, in this case the flexible printed circuit board fulfills both the object of electrical contacting and the object of mechanically and movably retaining the carrier by way of elastic or flexible rib-shaped retaining structures.

WO 2014/083 318 A1 and WO 2013/175 197 A1 each disclose an optical image stabilization system for a movable arrangement of a camera lens which is carried by a bending element or a spring plate on a stationary support arrangement, which act as springs in order to enable the movement relative to the stationary support arrangement. Wires made of shape memory alloy serve to this end, with the resilience being actuated by applying electrical drive signals to the wires.

Further, WO 2016/089 956 A1 also discloses an optical image stabilization system for a camera lens element, for example in cellular telephones.

US 2020/0 124 839 A1 has disclosed an optical image stabilizer (OIS) for use in portable devices. The device is equipped with at least one camera lens arrangement and the image stabilizer is equipped with an image sensor Flexible retaining structures serve to compensate for the movement of an optical element connected to a lens element.

Further, US 2017/0 261 762 A1 has disclosed an image stabilization mechanism with a movable element which holds an optical lens element, wherein the movable element is pressed against a stationary element by means of tension springs.

CN 1 12 399 043 A has disclosed an optical image stabilizer having an actuation element comprising a mount, and an image sensor. In the case of impact, the mount is attracted by an electrostatic attractive force, with the result that the image stabilizer is freed from a suspension structure and the image sensor is in a non-sprung state, whereby the optical image stabilizer is stabilized.

In this context, the electrical contacting was found to be problematic, especially in the transition region between the carrier of the image sensor and the holder in the housing of the mobile device of the image sensor which is movable vis-à-vis the carrier and hence vis-à-vis the stationary mobile device. In particular, there is a relationship between the desired simple and resistance-free movement of the image sensor on the one hand and the loadability and reliability of the electrical connections to the image sensor on the other hand in the prior art.

Moreover, in practice, an optimal function of the image stabilizer requires a plane movement of the carrier plate of the image sensor during the mechanical deflection by means of the actuators because otherwise aberrations arise. A disadvantage in the prior art was found in the largely directionally independent deformability of the printed circuit board, with the result that there is an unwanted “out of plane” movement of the carrier, i.e. a deflection of the carrier plate out of the plane.

Due consideration has already been given to the idea of restricting the mobility to the desired plane movement by way of additional guides, for example sliding guides. Even though such guides have already been found to be realizable in principle, they are accompanied by an increase in frictional resistances and hence a delay in the reaction speed.

### SUMMARY

In an embodiment, the present disclosure provides an optical image stabilizer for application in a mobile device equipped with at least one camera lens arrangement. The optical image stabilizer includes a carrier, elastic and/or flexible retaining structures that are rib-shaped, and an image sensor arranged on the carrier. The carrier is arranged so as to be movable with regard to a holder of the mobile device by the retaining structures, and is electrically connected by conductor tracks such that, for compensating for movements of the mobile device, the image sensor is arranged on the carrier so as to be movable relative to the holder by actuators. The retaining structures are at least in part elastically deformable and at least portions of the retaining structures consist of glass. At least some of the retaining structures have a width in a direction of a movement plane of the image sensor which is smaller than a material thickness in a direction transverse to the movement plane.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a plan view of an optical image stabilizer with retaining structures in a schematic diagram; and

FIG. 2 shows, in a schematic diagram and in a section along the line II-II, an enlarged representation of the retaining structures of the image stabilizer shown in FIG. 1.

### DETAILED DESCRIPTION

Embodiments of the present invention provide an optical image stabilizer with which image capture by means of the image sensor is substantially improved.

Thus, according to an embodiment of the present invention, an optical image stabilizer is provided, wherein the retaining structures have an elastically deformable embodiment and at least portions thereof consist of glass, wherein at least some of the in particular rib-shaped retaining structures have a width in the direction of a movement plane of the image sensor on the carrier which is smaller than the material thickness transversely or orthogonal to the movement plane. An embodiment of the present invention is based on the discovery of realizing a retaining structure made of glass which is designed as a microelectromechanical system (MEMS) and in which the extents of the rib-shaped retaining structures in the various directions of their cross sectional plane deviate significantly from one another. To attain the desired mobility, the retaining structure has high flexibility or elasticity on its carrier in the plane of main extent of the image sensor corresponding to the movement plane and has high inherent stiffness in a transverse direction to this plane. To this end, the rib-shaped retaining structures have a smaller width in the direction of the plane than in the transverse direction to this plane. As a result, this allows elastic or flexible properties of the rib-shaped retaining structures to be realized, said properties being strongly directionally dependent and optimally restricted to the plane of the image sensor such that, during usual operation of the optical image stabilizer, an unwanted “out of plane” movement out of the predetermined movement plane can be at least almost avoided.

Advantages of embodiments of the present invention consist not only in the significantly smaller width in relation to the material thickness of the rib-shaped structures, which is also referred to as height or depth, but especially also in the possibility according to embodiments of the present invention of generating a defined cross-sectional shape which has been optimized for the use purpose and which can moreover vary as required and/or in portions over the course of the main extent of the rib-shaped structure. To this end, it is possible to realize virtually any cross-sectional shapes, for example also convex cross-sectional shapes, of the rib-shaped structures. Therefore, the degrees of freedom of movement are optimized with regards to the translational movement in the x- and y-directions transverse to the optical axis and optionally to a rotational movement about the optical axis.

The cross-sectional shape of the retaining structures is preferably polygonal, in particular rectangular, with arched concave or convex circumferential regions not being precluded according to an embodiment of the present invention.

Even though adjacent rib-shaped retaining structures are preferably spatially separated from one another at a distance along their extent, i.e. do not have direct transverse connections, the inventive concept also includes those retaining structures in which the rib-shaped regions are interconnected in sections by transverse connections or which are separated from one another only by way of groove-shaped cutouts.

In addition to the low sensitivity in relation to an “out of plane” movement, the image stabilizer according to an embodiment of the present invention was also found to excel especially in terms of the high speed of possible movement and the mechanical quality, whereby a substantial improvement of the image quality is attained within the scope of the image recording by such devices.

It should be emphasized that embodiments of the present invention by no means preclude a deflection, in the form of a tilt movement, of the image sensor out of the plane of main extent, i.e. a pivoting movement about an axis in the plane of the image sensor. Rather, it is to be expected that future developments of the optical image stabilizers will require further degrees of freedom. The optical image stabilizer according to an embodiment of the present invention is already particularly suitable for such applications as well, by virtue of the elevated inherent stiffness of the retaining structures preventing or impeding a deflection as a displacement out of the plane of the image sensor as a matter of principle. The resistance, attained by the aspect ratio, to such a frequently unwanted deflection could however be overcome by correspondingly stronger actuators, and so this type of deflection is implemented not as a consequence of an acceleration of the device but only on account of appropriate control signals.

A particularly advantageous embodiment of the present invention is achieved by virtue of the retaining structures having a cross-sectional shape with a ratio of the width to the height of the cross section of between 1:2 and 1:10 as aspect ratio, with the result that the thickness or depth or height of the rib-shaped retaining structures is a multiple of their width. Naturally, the ratio may vary over the course of the longitudinal extent of the rib-shaped retaining structures.

The retaining structures could be coupled to spring elements which likewise consist of glass and for example are realized together as integral functional elements, in particular one-piece functional elements or functional elements produced in a uniform production method, together with the rib-like retaining structures by way of a MEMS structure. A particularly advantageous embodiment of the present invention is also achieved by virtue of the rib-shaped retaining structures being configured as spring elements by virtue of the glass material having elastic properties on account of the cross-sectional geometry of the rib-shaped retaining structures and being deflectable against its restoring force, which is different in different directions, by means of an actuator.

Another particularly advantageous embodiment of the present invention is achieved by virtue of the image sensor being arranged on a side of the carrier facing away from the camera lens arrangement, with the result that the carrier, which is transparent or transmissive at least in the relevant region, is arranged in the beam path of the exposure incident on the image sensor. Therefore, the carrier does not only serve the mechanical retention of the image sensor but also allows the optimization of the supplied exposure or radiation during the transmission through the carrier. For example, a polarization filter or a lens element can be an integral component part of the carrier, wherein the image sensor is optimally protected from ambient influences and the effects of mechanical force at the same time.

For example, it was also found to be advantageous if at least portions of the carrier and/or the retaining structures are provided with a coating such that only certain wavelength ranges of the incident radiation of the exposure are transmitted or reflected, for example in order thus to filter bothersome scattered radiation or protect the image sensor from unwanted radiation. Optionally, the carrier may also adopt the function of an optical element.

Another, likewise particularly advantageous embodiment of the present invention is also achieved by virtue of at least some of the rib-shaped retaining structures comprising an electrically conductive coating, thus in particular forming a conductor track, with the result that the function of signal transmission and power supply is integrated in the rib-shaped retaining structures at the same time. For example, the conductor tracks can also be arranged in a groove-shaped depression and/or be covered by an insulation layer, in order thus to achieve optimal protection against damage and malfunctions.

Particularly preferably, the image sensor is arranged on the carrier so as to be translationally and/or rotationally movable in the plane of main extent, with at least two, preferably three degrees of freedom, wherein further degrees of freedom may be integrated in the retaining structures or may be achieved by supplementary further retaining structures which enable a tilting movement of the image sensor out of the plane.

Furthermore, an optical image stabilizer with which image capture by means of the image sensor is substantially improved according to an embodiment of the present invention is also achieved with a portable device equipped with an optical image stabilizer, by virtue of the retaining structures for the carrier of the image sensor having an elastically deformable embodiment and at least portions thereof consisting of glass, wherein at least some of the in particular rib-shaped retaining structures have a width in the direction of a movement plane of the image sensor which is smaller than the material thickness in a transverse direction to the movement plane. An embodiment of the present invention is based on the insight that a cross-sectional shape of the rib-shaped retaining structures is realized according to the principle of a carrier plate made of glass as MEMS structure, the cross-sectional shape having great flexibility or elasticity in the plane of the plate and a high inherent stiffness in a transverse direction to the plane. In particular, the rib-shaped structures have a significantly smaller width in the direction of the plane than in the transverse direction to this plane. Moreover, it is possible to realize virtually any cross-sectional shapes, in particular also convex cross-sectional shapes, of the rib-shaped structures. At the same time, the electrical contacting can be integrated in the rib-shaped structures using methods known per se and without modifying the mechanical properties.

By virtue of using glass as material, it is also possible to arrange the optical sensor on the back side of the carrier plate, with the result that the glass can thus be located in the beam path of the light incident on the sensor, whereby the sensor is additionally protected or it is possible to make do without a separate protective glass.

According to an embodiment of the present invention, a method for producing elastic and/or flexible retaining structures for an optical image stabilizer is also provided, wherein a substrate made of glass and serving as carrier for an image sensor is provided with modifications in said substrate by means of laser radiation, wherein the focus of the laser radiation experiences spatial beam shaping along a beam axis of the laser radiation and said modifications are generated along said beam axis by means of said laser radiation, with the result that subsequently the action of an etching medium and successive etching as a consequence of the anisotropic material ablation in the respective region of the modifications leads, by way of line-shaped and/or groove-shaped cutouts, to elastically deformable rib-shaped retaining structures with a cross-sectional shape being created in the substrate, the width of said cross-sectional shape in the plane of the plane of main extent of the optical sensor being substantially smaller than the material thickness in a transverse direction to the plane of main extent. During the deflection, this achieves a largely planar movement of the image sensor on the carrier vis-á-vis the stationary holder of the mobile device. In this context, it was already found to be particularly advantageous to apply the laser induced deep etching (LIDE) method, wherein a change in the modifications along the optical axis leads in the subsequent etching method to the generation of the rib-shaped retaining structures not only with a rectangular cross-sectional shape with rounded-off edges, but for example also with convex constrictions.

In an embodiment, the image stabilizer is equipped with a sensor system which renders a relative deflection of the movable part vis-à-vis the carrier detectable. For example, to this end, permanent magnets are realized on or in the carrier or in the proximity of the movable region or in the movable region. The relative deflection is detected by way of magnetic field sensors in the movable part or in the carrier, for example Hall sensors. The sensors are electrically connected to the carrier by way of conductor tracks which preferably run along the retaining structures or spring structures.

By preference, the image stabilizer comprises an integrated actuator system for compensating for movements.

According to a further preferred embodiment, the image stabilizer is equipped with an integrated actuator system which enables a controlled deflection of the image sensor vis-à-vis the carrier in at least three degrees of freedom and/or with a deflection range of +/−75 μm. The actuator system reacts to the measurement signal from a sensor measuring the relative deflection. One form of actuator system is given by an electromagnet which generates a force when voltage is applied in the magnetic field of a permanent magnet. In this case, electromagnet and permanent magnet are situated on the carrier and on the movable part, respectively.

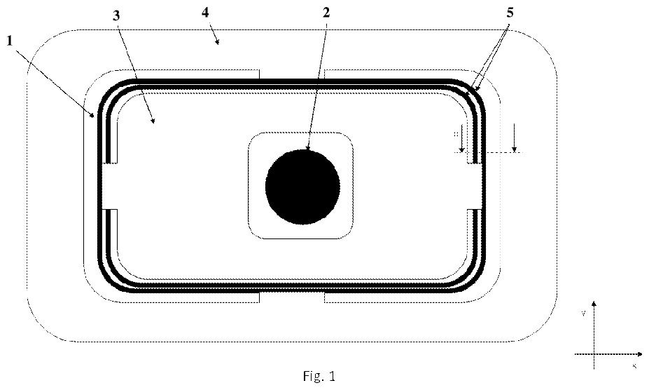

An optical image stabilizer 1 and a holder 4 of a mobile terminal are visible in a plan view in FIG. 1. In contrast to a camera lens arrangement associated with the terminal, an image sensor 2 is arranged on a carrier 3 of the image stabilizer 1. The carrier 3 is arranged so as to be movable vis-à-vis the holder 4 of the mobile terminal by means of flexible retaining structures 5 and is electrically connected by way of conductor tracks on the retaining structures 5.

Bothersome movements of the terminal are detected by sensors and compensated for by means of actuators by virtue of the image sensor 2, together with the carrier 3, being moved relative to the holder 4 by means of the actuators.

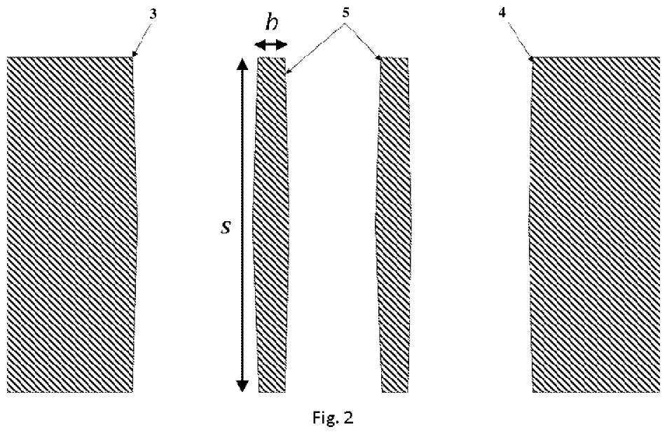

As depicted in FIG. 2 in particular, the retaining structures 5 consisting of glass are elastically deformable to this end and thus form spring elements, wherein the rib-shaped retaining structures 5 have a width b in the direction of a movement plane xy of the image sensor 2 which is smaller than the material thickness s in a transverse direction to the movement plane xy. In the exemplary embodiment, which is not depicted true to scale here, the ratio of the width b to the material thickness s is approx. 1:50.

This achieves optimum mobility by way of a high flexibility and elasticity on the carrier 3 of the image sensor 2 vis-à-vis the holder 4 in the plane of main extent of said image sensor which corresponds to the movement plane xy and by way of a high inherent stiffness orthogonal to the movement plane xy.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 Image stabilizer
2 Image sensor
3 Carrier
4 Holder
5 Retaining structure
s Material thickness
b Width
xy Movement plane

1: An optical image stabilizer for application in a mobile device equipped with at least one camera lens arrangement, the optical image stabilizer comprising:
a carrier:
elastic and/or flexible retaining structures that are rib-shaped; and
an image sensor arranged on the carrier,
wherein the carrier is arranged so as to be movable with regard to a holder of the mobile device by the retaining structures, and is electrically connected by conductor tracks such that, for compensating for movements of the mobile device, the image sensor is arranged on the carrier so as to be movable relative to the holder by actuators,
wherein the retaining structures are at least in part elastically deformable and at least portions of the retaining structures consist of glass, and
wherein at least some of the retaining structures have a width in a direction of a movement plane of the image sensor which is smaller than a material thickness in a direction transverse to the movement plane.

2: The optical image stabilizer as claimed in claim 1, wherein the retaining structures have a cross-sectional shape with a ratio of width to height of the cross-sectional shape of between 1:2 and 1:100.

3: The optical image stabilizer as claimed in claim 1, wherein the retaining structures are embodied as spring elements.

4: The optical image stabilizer as claimed in claim 1 wherein the image sensor is arranged on a side of the carrier facing away from the camera lens arrangement such that the carrier is arranged in a beam path of exposure incident on the image sensor.

5: The optical image stabilizer as claimed in claim 1 wherein at least portions of the carrier and/or retaining structures are provided with a coating such that only certain wavelength ranges of incident radiation are transmitted, reflected, diffracted, and/or refracted.

6: The optical image stabilizer as claimed in claim 1 wherein at least some of the retaining structures have an electrically conductive coating.

7: The optical image stabilizer as claimed in claim 1, wherein the image sensor is arranged on the carrier so as to be translationally and/or rotationally movable in a plane of main extent, with at least two degrees of freedom.

8: The optical image stabilizer as claimed in claim 1, further comprising an integrated actuator system with at least three degrees of freedom and/or a deflection range of +/−75 μm, for the compensating for the movements.

9: A mobile device having the optical image stabilizer as claimed in claim 1.

10: A method for producing elastic and/or flexible retaining structure for an optical image stabilizer, the method comprising:
providing a substrate made of glass and serving as a carrier for an image sensor with modifications in the substrate by laser radiation, wherein a focus of the laser radiation experiences spatial beam shaping along a beam axis of the laser radiation and the modifications are generated along the beam axis by the laser radiation, and
generating line-shaped and/or groove-shaped cutouts in the substrate by action of an etching medium and by successive etching as a consequence of anisotropic material ablation in respective regions of the modifications, the modifications forming elastically deformable rib-shaped retaining structures with a cross-sectional shape whose width in a plane of the movement plane of the image sensor is substantially smaller than a material thickness in a direction transverse to the movement plane of the image sensor.

11: A method for producing elastic and/or flexible retaining structures for an optical image stabilizer, the method comprising:
using laser induced deep etching to introduce line-shaped and/or groove-shaped recesses in a substrate made of glass and serving as a carrier for an image sensor, and to generate elastically deformable rib-shaped retaining structures with a cross-sectional shape whose width in a plane of the movement plane of the image sensor is substantially smaller than a material thickness in a direction transverse to the movement plane) of the image sensor.

12: The optical image stabilizer as claimed in claim 2, wherein the ratio of width to height of the cross-sectional shape is between 1:10 and 1:50.

13: The optical image stabilizer as claimed in claim 7, wherein the image sensor is arranged on the carrier so as to be translationally and/or rotationally movable in the plane of main extent, with three degrees of freedom.
